(19) United States
(12) Patent Application Publication
(10) Pub. No.: US 2017/0110355 A1
(43) Pub. Date: Apr. 20, 2017

(54) SUBSTRATE CLEANING APPARATUS AND METHOD FOR CLEANING SUBSTRATE FOR SUBSTRATE RELATED TO PHOTOMASK

(71) Applicant: SHIN-ETSU CHEMICAL CO., LTD., Tokyo (JP)

(72) Inventors: Tsuneo NUMANAMI, Jyoetsu (JP); Yukio INAZUKI, Jyoetsu (JP); Toyohisa SAKURADA, Jyoetsu (JP)

(73) Assignee: SHIN-ETSU CHEMICAL CO., LTD., Tokyo (JP)

(21) Appl. No.: 15/283,896

(22) Filed: Oct. 3, 2016

(30) Foreign Application Priority Data
Oct. 20, 2015 (JP) 2015-206607

(51) Int. Cl. H01L 21/68; H01L 21/67; H01L 21/687

(52) U.S. Cl. CPC H01L 21/68; H01L 21/68778; H01L 21/67051

(57) ABSTRACT

The present invention provides a substrate cleaning apparatus for a substrate related to a photomask, including a holder for holding only an end face of the substrate, a rotation mechanism for rotating the holder, and a nozzle for supplying liquid at least to the front surface of the substrate rotating with the holder by the rotation mechanism; wherein at least one of the holder has a conductive surface and is earthed. The present invention also provides a method for cleaning a substrate related to a photomask. These inventions can prevent adhesion of contaminants to the substrate when performing a cleaning treatment.

### TECHNICAL FIELD

The present invention relates to a substrate cleaning apparatus and a method for cleaning a substrate to clean a substrate related to a photomask.

### BACKGROUND ART

As an apparatus for cleaning a substrate related to a photomask (a photomask-related substrate), it has been previously known a spin-type substrate cleaning apparatus.

In such a substrate cleaning apparatus, a substrate can be cleaned by setting the substrate on a holding base with a holder, rotating the held substrate, and supplying desired liquid onto the central rotating portion.

After cleaning the substrate, the substrate was subjected to spin-drying by use of centrifugal force caused by high-speed rotation of the holding base. After spin-drying, the rotation of the holding base is stopped, and the substrate is taken out from the holding base.

In general, when rotating a substrate to gain centrifugal force, a circular substrate is stable, however, an angular solid substrate (hereinafter, referred to as an angular substrate) such as a semiconductor substrate, a glass substrate for a liquid-crystal display panel, and a mask substrate for a semiconductor producing apparatus are not stable. Accordingly, it is a plausible idea that an angular substrate is cleaned while being held by a mechanism to hold the back of the substrate such as an electrostatic chuck to stick the back in order to securely hold the angular substrate, when the angular substrate is thin and light. The back cannot be stuck, however, particularly when it is a substrate for a photomask. In this case, since an angular substrate can be held by a holder at the end face thereof, the angular substrate comes to be rotated with the end face being held mainly.

In a method for cleaning a substrate in which liquid is supplied to the central rotating portion of the substrate and the supplied liquid is spread radially to spread the liquid on the solid substrate (hereinafter, simply referred to as a substrate) by using centrifugal force caused by the rotating substrate, various means have been generally carried out in order to avoid adhesion of particles to the substrate (Patent Literatures 1 to 4). For example, Patent Literature 1 discloses a substrate cleaning apparatus which provides an ultra-pure water-gushing nozzle and a standby room therefor separated from a substrate cleaning room by a partition to put on standby the ultra-pure water-gushing nozzle before and after cleaning the substrate with ultra-pure water.

### CITATION LIST

### Patent Literature

PATENT LITERATURE 1: Japanese Patent Application Publication No. 2011-043584
PATENT LITERATURE 2: Japanese Patent Application Publication No. 2008-130728
PATENT LITERATURE 3: Japanese Patent Application Publication No. 2009-021448
PATENT LITERATURE 4: Japanese Patent Application Publication No. 2010-091774

### SUMMARY OF INVENTION

### Technical Problem

There are various reasons for causing adhesion of contaminants (a generic name of the liquid scattered to the surrounding to be mists, particles in the surrounding, etc.) to a substrate. For example, it can be considered to be resulted from electrification by rotating the surface of the substrate at high speed, which generates friction against the atmosphere (air). The charged surface attracts contaminants drifting the surrounding, and the attracted contaminants can adhere to the substrate; can contaminate liquid dropped to the substrate with the contaminant, and can cause an electrostatic breakdown.

When manufacturing a photomask blank, such contaminants in the cleaning before deposition can be contaminants in each functional film of inorganic material during a deposition step. Such contaminants in the cleaning after deposition can be contaminants on the surface of a photomask blank, and can be contaminants in a coated resist in a resist coating step.

As a result, it is highly probable that these contaminants will be fatal defects as a photomask blank.

An electrostatic breakdown breaks a portion where that has generated, which causes a defect.

Accordingly, photomask blanks and so on, which are preferable to be denuded, are particularly desired to prevent electrification, which causes adhesion of contaminants and an electrostatic breakdown when cleaning a substrate.

The supplied liquid is preferable to have low resistivity. In many cases, however, the supplied liquid has high resistivity (e.g. ultra-pure water). In order to lower the resistivity of such liquid, a blend of gas or an addition of impurities can be conceived. However, they can cause particles, and are not preferable thereby.

The present invention was accomplished in view of the above-described problems. It is an object of the present invention to provide a substrate cleaning apparatus and a method for cleaning a substrate which are used for cleaning a substrate related to a photomask and can prevent adhesion of contaminants to a substrate in the cleaning.

### Solution to Problem

To achieve the foregoing object, the present invention provides a substrate cleaning apparatus for a substrate related to a photomask, comprising

a holder for holding only an end face of the substrate,

a rotation mechanism for rotating the holder, and

a nozzle for supplying liquid at least to the front surface of the substrate rotating with the holder by the rotation mechanism; wherein

at least one of the holder has a conductive surface and is earthed.

In cleaning a substrate, such a substrate cleaning apparatus can effectively prevent electrification of the substrate and adhesion of contaminants to the substrate.

The liquid is preferably supplied to a central rotating portion of the substrate.

Such a substrate cleaning apparatus can supply the liquid onto the whole surface of a substrate.

The rotation speed of the substrate may be 30 rpm or more and 1500 rpm or less.

When a substrate is rotated at such a high speed, the inventive substrate cleaning apparatus can prevent adhesion of contaminants to the substrate.

It is also preferred that the substrate be an angular substrate.

The inventive substrate cleaning apparatus can be particularly suitable to be used for cleaning an angular substrate.

In this case, it is preferred that the holder hold the angular substrate only at the corner part of the angular substrate.

In such a substrate cleaning apparatus, even though the supplied liquid had hit the holder when the supplied liquid is spread by centrifugal force, there is few risk of adhesion of the scattered contaminants to the substrate again since the holder(s) locates at the outermost peripheral end of the rotation of the substrate.

The liquid supplied from the nozzle can be cleaning liquid, and the substrate may be treated for cleaning with the cleaning liquid.

As described above, the present invention can be particularly suitable to be used for cleaning a substrate.

The substrate may be a nonconductor.

The substrate may be a glass substrate. As the glass substrate, a quartz glass is preferable.

The inventive substrate cleaning apparatus can prevent adhesion of contaminants to the substrate even though the substrate is a nonconductor (e.g. a glass substrate), which is liable to charge.

The foregoing liquid may be a nonconductor.

The inventive substrate cleaning apparatus can prevent adhesion of contaminants to a substrate and an electrostatic breakdown even though the liquid is a nonconductor (e.g. ultra-pure water), which is liable to charge.

The present invention further provides a method for cleaning a substrate related to a photomask, comprising the steps of:

holding only an end face of the substrate with a holder,

rotating the holder to rotate the substrate,

supplying liquid at least to the front surface of the substrate, and

spreading the liquid on the substrate to clean the substrate; wherein

at least one of the holder has a conductive surface and is earthed.

When cleaning is performed, such a method for cleaning a substrate can effectively prevent electrification of the substrate and adhesion of contaminants onto the substrate.

The liquid is preferably supplied to a central rotating portion of the substrate.

Such a method for cleaning a substrate can supply the liquid onto the whole surface of a substrate.

The rotation speed of the substrate can be 30 rpm or more and 1500 rpm or less.

When a substrate is rotated at such a high speed, the inventive method for cleaning a substrate can prevent adhesion of contaminants to the substrate.

It is also possible to obtain a preferable result even though the substrate is an angular substrate.

The inventive method for cleaning a substrate can be particularly suitable to be used for cleaning an angular substrate.

In this case, it is preferred that the holder hold the angular substrate only at the corner part of the angular substrate.

The liquid can be cleaning liquid, and the substrate can be treated for cleaning with the cleaning liquid.

As described above, the inventive method for cleaning a substrate can be particularly suitable to be used for cleaning a substrate.

The substrate can be a nonconductor.

The substrate can be a quartz glass substrate. As the glass substrate, a quartz glass is preferable.

The inventive method for cleaning a substrate can prevent adhesion of contaminants to the substrate even though the substrate is a nonconductor (e.g. a quartz glass substrate), which is liable to charge.

The foregoing liquid may be a nonconductor.

The inventive method for cleaning a substrate can prevent adhesion of contaminants to a substrate and an electrostatic breakdown even though the liquid is a nonconductor (e.g. ultra-pure water), which is liable to charge.

### Advantageous Effects of Invention

In performing a cleaning treatment, a substrate cleaning apparatus and a method for cleaning a substrate of the present invention can prevent electrification of the substrate and adhesion of contaminants to the substrate.

### BRIEF DESCRIPTION OF DRAWINGS

FIG. 1 is a schematic diagram showing one example of the inventive substrate cleaning apparatus;

FIG. 2 is a top view showing one example of the inventive substrate cleaning apparatus;

FIG. 3 is a top view showing another example of the inventive substrate cleaning apparatus;

FIG. 4 is a diagram showing a case to hold a square substrate in which each side of the substrate is held by a holder in the vicinity of its center;

FIG. 5 is a diagram showing a case to hold a square substrate in which each side of the substrate is held by plural holders in the vicinity of its center;

FIG. 6 is a diagram showing a case to hold a rectangular substrate in which each side of the substrate is held by plural holders in the vicinity of its center;

FIG. 7 is a diagram showing a case to hold a square substrate in which each of the four corners of the substrate is held by holders;

FIG. 8 is a diagram showing a case to hold a rectangular substrate in which each of the four corners of the substrate is held by holders;

FIG. 9 is a diagram showing a case to hold a rectangular substrate in which each side of the substrate is held by holders in the vicinity of its center, and to rotate the substrate;

FIG. 10 is a diagram showing a case to hold a rectangular substrate in which each of the four corners of the substrate is held by holders, and to rotate the substrate;

FIG. 11 is a diagram showing a holder which is in full contact with the side face of a substrate;

FIG. 12 is a diagram showing a holder which is in contact with the side face of a substrate with having a gap;

FIG. 13 is a flow chart showing an example of a process of a method for cleaning a substrate of the present invention;

FIG. 14 is a diagram showing the arrangement of holders in Example 1;

FIG. 15 is a diagram showing the arrangement of holders in Comparative Example 1;

FIG. 16 is a SEM (scanning electron microscope) image of a defect after performing Example 1;

FIG. 17 is a SEM image of a defect after performing Comparative Example 1;

FIG. 18 is an AFM (atomic force microscope) image of a defect after performing Example 1;

FIG. 19 is an AFM image of a defect after performing Comparative Example 1;

FIG. 20 is a graph showing depth of the defect in the section at the straight line in FIG. 18;

FIG. 21 is a graph showing depth of the defect in the section at the straight line in FIG. 19.

### DESCRIPTION OF EMBODIMENTS

Hereinafter, the present invention will be described more specifically.

As described above, it has been required for a substrate cleaning apparatus and a method for cleaning a substrate which are used for a substrate related to a photomask and can prevent adhesion of contaminants to a substrate when cleaning treatment is performed.

The present inventors have diligently studied to achieve the foregoing object and have consequently found that it is possible to prevent electrification of the surface of a rotating substrate and to prevent adhesion of contaminants to a substrate, when the substrate is supplied with liquid, by a substrate cleaning apparatus for a substrate related to a photomask in which at least one holder to hold an end face of the rotating substrate has a conductive surface and is earthed, and a method for cleaning a substrate related to a photomask in which at least one holder has a conductive surface and is earthed; thereby bringing the present invention to completion.

Hereinafter, embodiments of the present invention will be specifically described with reference to figures, but the present invention is not limited thereto.

### [Substrate Cleaning Apparatus]

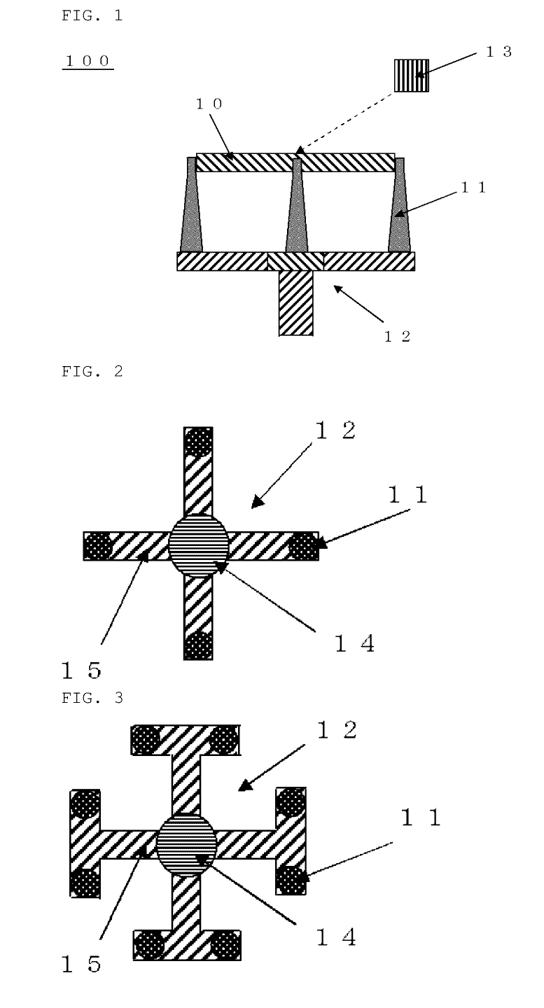

First, the inventive substrate cleaning apparatus will be described. FIG. 1 is a schematic diagram showing one example of an inventive substrate cleaning apparatus; and FIG. 2 is a top view showing one example of an inventive substrate cleaning apparatus. As described in FIGS. 1 and 2, the inventive substrate cleaning apparatus 100 is provided with a holder(s) 11 for holding only an end face of a substrate 10, a rotation mechanism 12 for rotating (revolving) the holder(s) 11, and a nozzle 13 for supplying liquid at least to the front surface of the substrate 10 rotating with the holder 11 by the rotation mechanism 12. In the inventive substrate cleaning apparatus 100, at least one of the holder 11 has a conductive surface and is earthed. It is to be noted that the holder 11 can be arranged as shown in FIG. 3, which is a top view showing another example of the inventive substrate cleaning apparatus. This can holds the four corners of a square by the holders 11.

The inventive substrate cleaning apparatus is used for cleaning a substrate related to a photomask. The shape of a substrate to be held, although it is not particularly limited, includes a circular substrate, an angular substrate, etc.

The substrate related to a photomask herein includes a substrate for a photomask, a photomask blank which is obtained by depositing one or more inorganic layer(s) onto this substrate for a photomask, a photomask made from by processing this photomask blank (a mask substrate for a semiconductor manufacturing apparatus), and an intermediate in a photomask blank production in the middle of producing a photomask blank on which plural of inorganic films are deposited; and also includes an intermediate in producing a photomask such as a photomask blank with a resist in the middle of processing with the photomask blank, etc.

Illustrative examples of the substrate for a photomask include a substrate with translucency to various wavelength of exposure light (a transparent substrate) such as quartz glass, calcium fluoride, etc. In the present invention, the substrate to be held can be also a nonconductor such as a glass substrate being liable to charge. As the glass substrate, a quartz glass is preferable. The inventive substrate cleaning apparatus can effectively discharge static electricity and prevent adhesion of contaminants even when such a substrate is cleaned.

Among them, a photomask, a photomask blank, and a substrate in the middle of these steps made of an angular substrate, which is particularly a quartz substrate (a glass substrate), are thick and heavy, contain insulated substrates, and are preferable to be denuded. Accordingly, it is particularly desirable to treat them by using the inventive substrate cleaning apparatus in order to prevent electrification to prevent adhesion of contaminants to a substrate, which causes a defect.

The shape of the holder, which is not particularly limited, includes a cylindrical shape and a platy shape, for example.

The material of the holder, which is not particularly limited, includes metal, resin, etc. Illustrative examples of the resin include polyether ether ketone resin (PEEK resin), polyphenylene sulfide resin (PPS resin), etc. Such a holder which contains resin can prevent a scratch on the end face and give good cleanness and processing accuracy. Illustrative examples of the metal include aluminum and stainless material. The holder containing such metal is not necessary to be separately given conductivity.

When resin is used as a material of the holder, the holder preferably contains conductive filler such as carbon particle, metal particle, etc. to provide conductivity in order to have a conductive surface. It is also preferable to coat the surface with a metal film, conductive resin, etc.

The number of the holder is not particularly limited, but it can be 4 to 8 pieces for example, as shown in FIGS. 1 to 3. The present invention is adequate so long as at least one of the holder is a holder having a conductive surface (a conductive holder) in all of the holders to hold a substrate. For example, when a substrate is held by 8 holders, even though the 7 holders of them do not have conductivity, it is not a problem so long as the residual one holder is a conductive holder. In this case, the residual one holder has to be earthed. In order to sufficiently prevent electrification, it is preferred that two or more, particularly all of the holders be conductive holders.

In the latter case, the end face of a substrate is in contact with any one of the conductive holder, and accordingly, it is possible to discharge static electricity more securely during cleaning of a substrate even though the substrate is set to a different position due to the dimensional tolerance of the substrate or mechanical control.

The conductive holder can be earthed (grounded), for example, by connecting wire (not shown in figures).

The place to set the holder is not particularly limited. The place to set may be altered in accordance with the shape of a substrate to be cleaned. Hereinafter, the case to hold an angular substrate will be described.

When an angular substrate is held at the end face thereof, it is desirable to deduce the centroid of the substrate and to set the holder(s) so as to rotate the angular substrate around the centroid.

It is desirable to set (arrange) the holders at symmetrical positions to each of the sides of a substrate since this stabilizes the holding. When sufficient holding can be achieved, it is possible to omit a part of these holders. Alternatively, when the holding is unstable, it is desirable to appropriately set an auxiliary holder(s) in addition to the symmetrically arranged holders to prevent falling and getting out of an angular substrate from the holder.

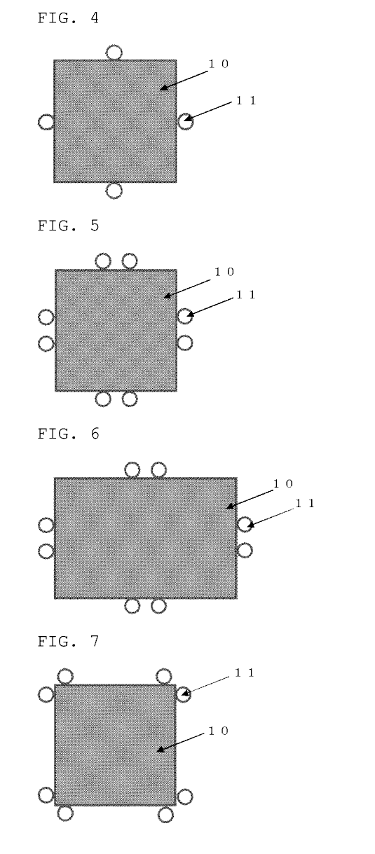

As an example of arrangement of holders, regarding an angular substrate near a square, include an arrangement of holders to hold the center portion (the vicinity of the center) of each side of the substrate (see FIG. 4 and FIG. 5). When the angular substrate is rectangle and gets unstable during the rotation, it is preferable to arrange the holders so as to hold each side of the substrate by plural holders (see FIG. 6).

Other modes include an arrangement in which holders hold an angular substrate only at the corner parts of the substrate (only at the four corners when the substrate is a tetragon) (see FIG. 7 and FIG. 8). Particularly, when the shape of a substrate is a rectangle, such an arrangement to hold the vicinities of four corners of the substrate is preferable (see FIG. 8).

In a regular polygonal substrate, illustrative examples of an arrangement of holders include an arrangement to hold the vicinity of the center of each side, and an arrangement to hold only at the corner parts of the substrate. Also in the polygonal substrate, it is preferable to arrange the holders only at the corner parts of the substrate.

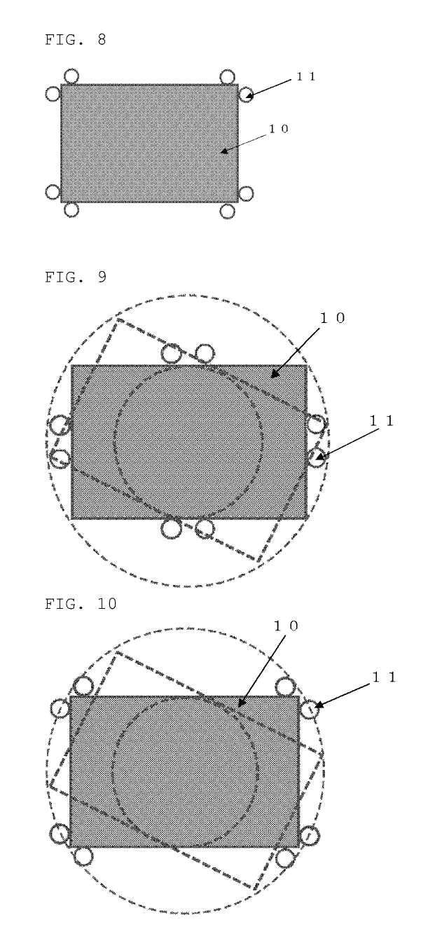

In an arrangement to hold only four corners (corner parts in a polygonal substrate), the holders are arranged at the extension of a diagonal of a substrate. Accordingly, when the supplied liquid is spread by centrifugal force, the holders locate at the outermost peripheral ends in rotating the substrate. Therefore, if the supplied liquid hit on the holder, there is a few risk of re-adhesion of scattered contaminants to the substrate (see FIG. 10). On the other hand, when the center portions of the sides are held, contaminants are hard to adhere to inner circumference of a circle with the radius being a distance between the center of rotation and the center of the side. However, the supplied liquid can hit on the holder holding the long side of the substrate, and contaminants can be scattered to the periphery of the substrate. Accordingly, contaminants can adhere to the periphery in higher possibility (see FIG. 9).

The rotation mechanism 12 can be a mechanism previously used in a spin-type substrate cleaning apparatus to hold the end face of a substrate, and its shape and so on are not particularly limited. It can have a rotation axis 14 and supporter 15 to support holders as shown in FIGS. 2 and 3. The rotation speed of the rotation mechanism is not particularly limited. For example, it is preferred that the rotation speed of the substrate 10, which rotates with the holders 11 by the rotation mechanism 12, is 30 rpm or more and 1500 rpm or less. When the substrate rotates in such high speed, the inventive substrate cleaning apparatus can prevent adhesion of contaminants to a substrate.

The nozzle 13 can be a nozzle previously used in a spin-type substrate cleaning apparatus, and its shape and so on are not particularly limited. The nozzle 13 have only to supply liquid at least to the front surface of the substrate. It is preferred that the nozzle 13 supply liquid to a central rotating portion of the substrate 10. Such a substrate cleaning apparatus can supply liquid onto the whole surface of a substrate. In this case, it is possible to provide another nozzle to supply liquid to the periphery of the substrate 10. It is also possible to separately provide a nozzle to supply liquid to the back surface of the substrate 10, or further provide a nozzle to supply liquid to the side face etc. By providing a nozzle to supply liquid to the back surface, it is possible to clean the back surface simultaneously.

Illustrative examples of the liquid supplied from the nozzle include ultra-pure water, functional water (deaerated water, hydrogen water, etc.), and liquid using chemicals in cleaning performed during a step for manufacturing a photomask blank. When the liquid supplied from the nozzle is cleaning liquid, the substrate can be cleaned with the cleaning liquid.

As described above, the liquid supplied from a nozzle may be a nonconductor (e.g. ultra-pure water), which is liable to charge, in the present invention. The inventive substrate cleaning apparatus can prevent adhesion of contaminants to a substrate and an electrostatic breakdown even when such liquid is supplied to a substrate.

It is to be noted that the inventive substrate cleaning apparatus can be used in combination with an ionizer, an apparatus to give conductivity to the liquid, which have been used previously.

### [Method for Cleaning Substrate]

Subsequently, the inventive method for cleaning a substrate will be described. The inventive method for cleaning a substrate is a method for cleaning a substrate related to a photomask, comprising the steps of:

holding only an end face of the substrate 10 with a holder 11,

rotating (revolving) the holder 11 to rotate the substrate 10,

supplying liquid at least to the front surface of the substrate 10, and

spreading the liquid on the substrate 10 to clean the substrate 10; wherein

at least one of the holder 11 has a conductive surface and is earthed.

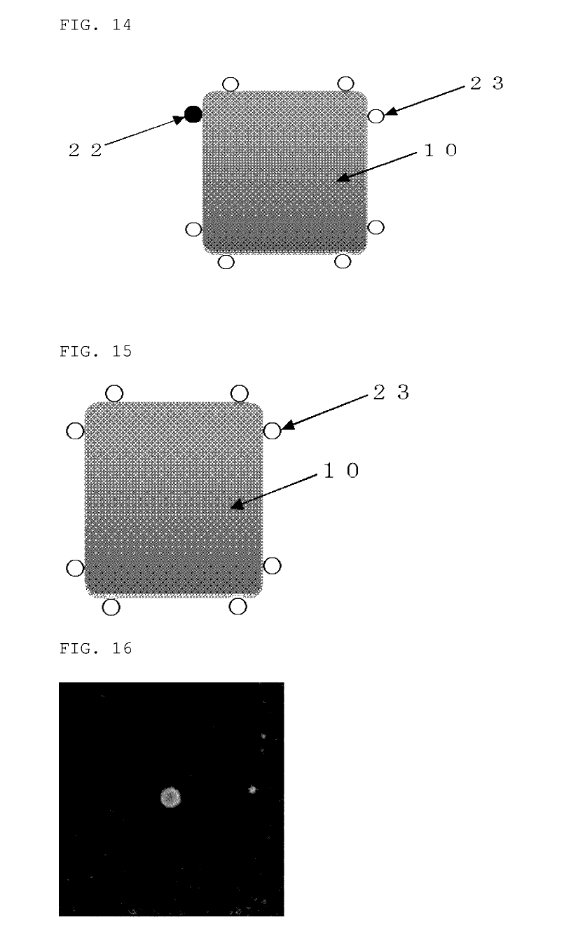

An example of a process of the inventive method for cleaning a substrate is shown in FIG. 13 in the form of a flow chart. First, as shown in (1) of FIG. 13, a substrate 10 is held by holders 11 only at the end face. In this case, the kind and shape of the substrate to be held, the material and arrange of the holder, etc. can be the same with the ones described in the foregoing term of a substrate cleaning apparatus.

In the present invention, it is desirable that the conductive holder is in full contact with the base.

Basically, it is desirable that each holder securely holds each end face of a substrate such as an angular substrate. In practical, however, it can have a problem such as accuracy in setting holders, gradual deformation of holders caused by repeated cleaning of a substrate, deformation of the holding mechanism itself to cause change of holding force of each holder.

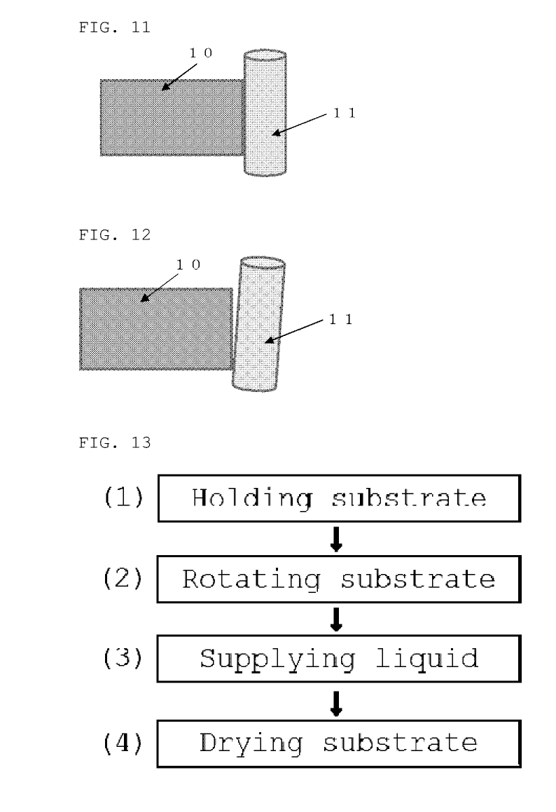

For example, while there is a holder which sufficiently holds the end face (side face) of a substrate (see FIG. 11), there can be a holder which is in contact with the side of a substrate with having a sort of “gap” (see FIG. 12). In this case, it is possible to remove electrification of a substrate, being charged due to various reasons, by providing conductivity at least to the contact portion(s) of a holder(s) sufficiently holding the end face of a substrate (to make the contact portion be conductive), and making the portion(s) provided with conductivity be earthed.

When a holder sufficiently holding a substrate causes deformation or deviation of the accuracy of its position through repeated cleaning of a substrate, it is possible to prevent electrification of a substrate with long-term stability by providing conductivity to every contact portion between a holder and substrate or every portion supposed to be in contact with a substrate, and making those portions given conductivity be earthed, in order to use them in an extent of ensuring safety rotation.

Alternatively, when a conductive holder is deformed, it is also possible to effectively prevent electrification of the surface of a substrate by exchanging the deformed conductive holder for a new conductive holder.

As described above, when holders form a portion which is sufficiently contact with the end face of a substrate and a portion which contains a sort of gap, it is possible to prevent electrification of the surface of a substrate more effectively by providing conductivity to holders (or portions thereof) sufficiently holding the end face of a substrate, and making those portions provided with conductivity be earthed.

Subsequently, the holders 11 are rotated to rotate the base 10, as shown in (2) of FIG. 13. The rotation speed of a substrate can be the same as described in the foregoing term of a substrate cleaning apparatus. It is to be noted that in cleaning of the substrate, the rotation speed of a substrate during cleaning can be set to 30 rpm or more and 100 rpm or less.

Then, liquid is supplied at least to the front surface of the substrate 10 to spread the liquid on the substrate 10 as shown in (3) of FIG. 13. The method for supplying liquid and so on can be the same as described in the foregoing term of a substrate cleaning apparatus. In this case, the temperature of liquid to be supplied can be set to the ambient temperature of 25° C., and the time supplying the liquid can be set to 90 to 120 seconds, but not limited thereto.

Subsequently, the substrate 10 can be dried as shown in (4) of FIG. 13. For example, when a substrate is cleaned with cleaning liquid, it is preferable to dry the substrate by spin-drying. The rotation speed of a substrate in this spin-drying can be set to about 1500 rpm.

### EXAMPLES

Hereinafter, the present invention will be more specifically described with reference to Examples and Comparative Examples, but the present invention is not limited thereto.

### Example 1

The front surface and the back surface of a photomask blank 6 inches square (152 mm×152 mm) with a thickness of 0.25 inch (6.35 mm) were cleaned by using the inventive substrate cleaning apparatus. The total 8 holders are arranged only at the corners of the substrate as shown in FIG. 14, with one of them being a conductive holder 22. As the conductive holder, conductive PPS (polyphenylene sulfide) loaded with carbon was used. The conductive holder was earthed. As the remaining 7 holders, PPS was used intact. That is, non-conductive holders 23 were used. As the cleaning liquid, deaerated water (DIW) and ammonia-added hydrogen water (H₂ water) were used. The temperature of the cleaning liquids were set to ordinary temperature of 25° C., and the supply time was set to 90 to 120 seconds (the longest supply time 120 seconds). The rotation speed of the substrate was set to 30 to 100 rpm (the maximum rotation speed 100 rpm).

The specific order of the cleaning steps are as follows:
1. back surface: DIW
2. back surface: DIW/front surface: addition of H₂ water
3. back surface: DIW/front surface: addition of H₂ water+MS (megasonic wave)
4. back surface: DIW/front surface: addition of H₂ water+MS/DIW
5. back surface: DIW/front surface: DIW

After finishing the above-described cleaning, the substrate was subjected to spin-drying. In this step, the rotation speed of the substrate was set to 1500 rpm.

### Comparative Example 1

The front surface and the back surface of a photomask blank was cleaned in the same conditions as in Example 1, except for using no conductive holder (see FIG. 15).

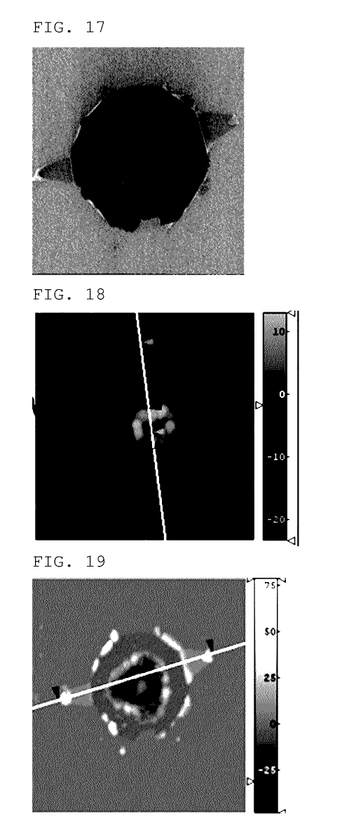

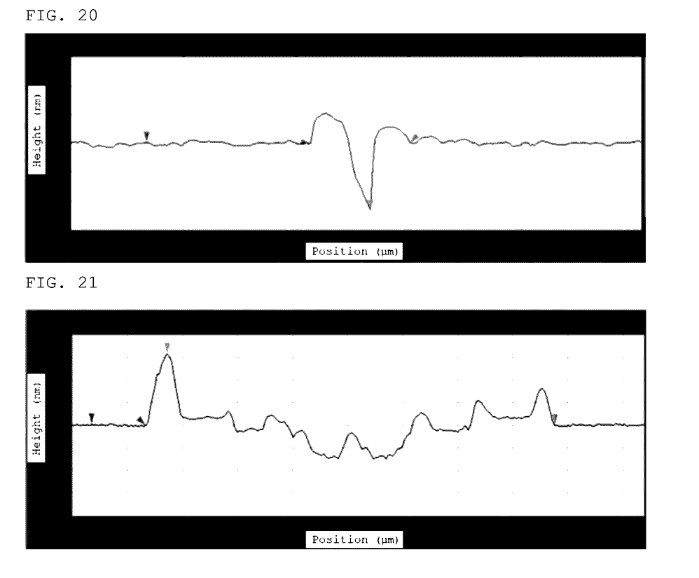

FIG. 16 is a SEM (scanning electron microscope) image of a defect after performing Example 1, and FIG. 17 is a SEM image of a defect after performing Comparative Example 1. FIG. 18 is an AFM (atomic force microscope) image of a defect after performing Example 1, and FIG. 19 is an AFM image of a defect after performing Comparative Example 1. FIG. 20 is a graph showing depth of the defect in the section at the straight line in FIG. 18, and FIG. 21 is a graph showing depth of the defect in the section at the straight line in FIG. 19. In FIGS. 18 and 19, the depths of each defect are represented by a shade (of color), and the values of depth (unit: nm) at the respective shades (colors) are shown in the right side of each image. In FIGS. 20 and 21, the ordinate shows height (unit: nm), and the abscissa shows the position of a defect (unit: μm). The position shown by the triangle in FIG. 18 corresponds to the position shown by the triangle in FIG. 20, and the position shown by the triangle in FIG. 19 corresponds to the position shown by the triangle in FIG. 21.

In Example 1 as shown in FIGS. 16, 18, and 20, the photomask blank showed a defect (peeling of the film) on its surface, but the size was small. On the other hand, in Comparative Example 1 as shown in FIGS. 17, 19, and 21, the photomask blank showed a large defect (peeling of the film) on its surface. It is supposed that in Example 1, a conductive holder was used, and electrification could be prevented effectively thereby, as a result, destruction of the substrate due to an electrostatic breakdown could be lowered.

Table 1 shows the total number of defects on the 30 substrates cleaned by the condition of Example 1, and the total number of defects on the 30 substrates cleaned by the condition of Comparative Example 1.

TABLE 1

| | Number of defects |
|---|---|
| Example 1 | 63 |
| Comparative Example 1 | 266 |

(total number per 30 samples)

As shown in Table 1, in Example 1, the total number of defects when 30 substrate had been cleaned was few or 63 points. On the other hand, in Comparative Example 1 as shown in Table 1, the total number of defects when 30 substrate had been cleaned was 266 point, that is, many defects was generated.

### Example 2

The front surface and the back surface of a photomask blank 6 inches square (152 mm×152 mm) with a thickness of 0.25 inch (6.35 mm) were cleaned by using the inventive substrate cleaning apparatus. The total 8 holders are arranged only at the corners of the substrate as shown in FIG. 14, with one of them being a conductive holder 22. As the conductive holder, conductive PPS (polyphenylene sulfide) loaded with carbon was used. The conductive holder was earthed. As the remaining 7 holders, PPS was used intact. That is, non-conductive holders 23 were used. As the cleaning liquid, deaerated water (DIW) and hydrogen water (H₂ water) were used. The temperature of the cleaning liquids were set to ordinary temperature of 25° C., and the supply time was set to 90 to 120 seconds (the longest supply time 120 seconds). The rotation speed of the substrate during the supply of the cleaning liquid was set to 30 rpm.

The specific order of the cleaning steps are as follows:
1. back surface: DIW
2. back surface: DIW/front surface: addition of H₂ water
3. back surface: DIW/front surface: addition of H₂ water+MS (megasonic wave)
4. back surface: DIW/front surface: addition of H₂ water+MS/DIW
5. back surface: DIW/front surface: DIW

After finishing the above-described cleaning, the substrate was subjected to spin-drying. In this step, the rotation speed of the substrate was set to 1500 rpm. The charge voltage (V) in the foregoing step 3 of this cleaning was measured with a digital static field meter (MODEL 2050, manufactured by Hugel Electronics Inc.). The measuring point was the center of the substrate.

### Example 3

The front surface and the back surface of a photomask blank 6 inches square (152 mm×152 mm) with a thickness of 0.25 inch (6.35 mm) were cleaned by using the inventive substrate cleaning apparatus. The total 8 holders are arranged only at the corners of the substrate as shown in FIG. 14, with all of them being conductive holders 22. As the conductive holder, conductive PPS (polyphenylene sulfide) loaded with carbon was used. The conductive holders were earthed. The front surface and the back surface of a photomask blank were cleaned in the same conditions as in Example 2, except the above-described holders, and the charge voltage (V) was measured as in Example 2.

### Comparative Example 2

The front surface and the back surface of a photomask blank was cleaned in the same conditions as in Example 2, except for using no conductive holder.

Table 2 shows charge voltages (V) measured in Example 2, Example 3, and Comparative Example 2.

TABLE 2

| | Charge voltage (V) |
|---|---|
| Example 2 | 1300 |
| Example 3 | 10 |
| Comparative Example 2 | 2300 |

As shown in Table 2, in Example 2, the charge voltage (V) is small compared to Comparative Example 2, which reveals that electrification of the surface of the substrate is suppressed.

From these results, it has revealed that in Example 2, electrification of a substrate is suppressed, thereby being hard to generate adhesion of contaminants and an electrostatic breakdown due to electrification of a substrate compared to Comparative Example 2.

In Example 3, the charge voltage (V) is further small compared to Comparative Example 2, which reveals that electrification of the surface of the substrate is considerably suppressed. From these results, it has revealed that in Example 3, electrification of a substrate is suppressed, thereby being remarkably hard to generate adhesion of contaminants and an electrostatic breakdown due to electrification of a substrate compared to Comparative Example 2.

It is to be noted that the present invention is not restricted to the foregoing embodiment. The embodiment is just an exemplification, and any examples that have substantially the same feature and demonstrate the same functions and effects as those in the technical concept described in claims of the present invention are included in the technical scope of the present invention.

1. A substrate cleaning apparatus for a substrate related to a photomask, comprising
a holder for holding only an end face of the substrate,
a rotation mechanism for rotating the holder, and
a nozzle for supplying liquid at least to the front surface of the substrate rotating with the holder by the rotation mechanism; wherein
at least one of the holder has a conductive surface and is earthed.

2. The substrate cleaning apparatus for a substrate related to a photomask according to claim 1, wherein the liquid is supplied to a central rotating portion of the substrate.

3. The substrate cleaning apparatus for a substrate related to a photomask according to claim 1, wherein the rotation speed of the substrate is 30 rpm or more and 1500 rpm or less.

4. The substrate cleaning apparatus for a substrate related to a photomask according to claim 1, wherein the substrate is an angular substrate.

5. The substrate cleaning apparatus for a substrate related to a photomask according to claim 4, wherein the holder holds the angular substrate only at the corner part of the angular substrate.

6. The substrate cleaning apparatus for a substrate related to a photomask according to claim 1, wherein the liquid supplied from the nozzle is cleaning liquid, and the substrate is treated for cleaning with the cleaning liquid.

7. The substrate cleaning apparatus for a substrate related to a photomask according to claim 1, wherein the substrate is a nonconductor.

8. The substrate cleaning apparatus for a substrate related to a photomask according to claim 1, wherein the substrate is a glass substrate.

9. The substrate cleaning apparatus for a substrate related to a photomask according to claim 1, wherein the liquid is a nonconductor.

10. A method for cleaning a substrate related to a photomask, comprising the steps of:
holding only an end face of the substrate with a holder,
rotating the holder to rotate the substrate,
supplying liquid at least to the front surface of the substrate, and
spreading the liquid on the substrate to clean the substrate; wherein
at least one of the holder has a conductive surface and is earthed.

11. The method for cleaning a substrate related to a photomask according to claim 10, wherein the liquid is supplied to a central rotating portion of the substrate.

12. The method for cleaning a substrate related to a photomask according to claim 10, wherein the rotation speed of the substrate is 30 rpm or more and 1500 rpm or less.

13. The method for cleaning a substrate related to a photomask according to claim 10, wherein the substrate is an angular substrate.

14. The method for cleaning a substrate related to a photomask according to claim 13, wherein the holder holds the angular substrate only at the corner part of the angular substrate.

15. The method for cleaning a substrate related to a photomask according to claim 10, wherein the liquid is cleaning liquid, and the substrate is treated for cleaning with the cleaning liquid.

16. The method for cleaning a substrate related to a photomask according to claim 10, wherein the substrate is a nonconductor.

17. The method for cleaning a substrate related to a photomask according to claim 10, wherein the substrate is a glass substrate.

18. The method for cleaning a substrate related to a photomask according to claim 10, wherein the liquid is a nonconductor.
